(19) United States
(12) Patent Application Publication
(10) Pub. No.: US 2022/0209064 A1
(43) Pub. Date: Jun. 30, 2022

(54) EPITAXY SUBSTRATE AND EPITAXIAL WAFER STRUCTURE

(71) Applicant: GlobalWafers Co., Ltd., Hsinchu (TW)

(72) Inventor: Wei Jie Sie, Hsinchu (TW)

(73) Assignee: GlobalWafers Co., Ltd., Hsinchu (TW)

(21) Appl. No.: 17/553,835

(22) Filed: Dec. 17, 2021

(30) Foreign Application Priority Data
Dec. 30, 2020 (TW) 109146841

(51) Int. Cl. H01L 33/22; H01L 33/00; H01L 33/12

(52) U.S. Cl. CPC H01L 33/22; H01L 33/12; H01L 33/0075

(57) ABSTRACT

An epitaxy substrate including a substrate and an aluminum nitride layer is provided. The substrate has a first surface and a second surface opposite to each other. The substrate has a ring-shaped protrusion on the edge of the second surface. The aluminum nitride layer is disposed on the first surface of the substrate. An epitaxial wafer structure is also provided.

### CROSS-REFERENCE TO RELATED APPLICATION

This application claims the priority benefit of Taiwan application serial no. 109146841, filed on Dec. 30, 2020. The entirety of the above-mentioned patent application is hereby incorporated by reference herein and made a part of this specification.

### BACKGROUND

### Technical Field

The disclosure relates to an epitaxy substrate and an epitaxial wafer structure, and particularly relates to an epitaxy substrate and an epitaxial wafer structure with ring-shaped protrusions.

### Description of Related Art

Epitaxial growth refers to the technology of growing new crystals on a substrate (such as a wafer) to form a semiconductor layer. Generally speaking, the substrate needs to be properly heated during the epitaxial growth process. However, if the temperature of the substrate is not evenly distributed; or, the stress is correspondingly increased due to the large radius of curvature (e.g., approximately less than −50 km⁻¹), it is possible to result in poor uniformity of the film thickness of the epitaxial layer or cause more cracks, which reduces the quality of the epitaxial layer.

Therefore, how to further improve the quality of the epitaxial layer has become an urgent problem to be solved at present.

### SUMMARY

The disclosure provides an epitaxy substrate, through which the epitaxial layer formed can have improved quality.

The epitaxy substrate of the disclosure includes a substrate and an aluminum nitride layer. The substrate has a first surface and a second surface opposite to each other. The substrate has a ring-shaped protrusion on the edge of the second surface. The aluminum nitride layer is located on the first surface of the substrate.

In an embodiment of the disclosure, the height of the ring-shaped protrusion is between 10 μm and 200 μm.

In an embodiment of the disclosure, the width of the ring-shaped protrusion is less than or equal to 5 mm.

In an embodiment of the disclosure, the thickness of the aluminum nitride layer is between 1 nanometer and 100 nanometers.

In an embodiment of the disclosure, the thickness of the substrate is between 625 μm and 1000 μm.

In an embodiment of the disclosure, the substrate includes a silicon material.

In an embodiment of the disclosure, the epitaxy substrate further includes a buffer layer. The buffer layer is located on the aluminum nitride layer. The lattice of the buffer layer is between the lattice of the aluminum nitride layer and the lattice of the gallium nitride epitaxial layer.

In an embodiment of the disclosure, the buffer layer includes a superlattice material.

In an embodiment of the disclosure, the bow of the epitaxy substrate is greater than −140 μm.

In an embodiment of the disclosure, the structure of the substrate consists of a first portion and a second portion, the second portion surrounds the first portion and corresponds to the ring-shaped protrusion, and the thickness of the second portion is greater than the thickness of the first portion.

The epitaxial wafer structure of the disclosure includes an epitaxy substrate and an epitaxial layer of an embodiment of the disclosure. The epitaxial layer is located on the aluminum nitride layer of the epitaxy substrate.

In an embodiment of the disclosure, the epitaxial wafer structure further includes a buffer layer. The aluminum nitride layer and the epitaxial layer directly contact the two opposite sides of the buffer layer, and the lattice of the buffer layer is between the lattice of the aluminum nitride layer and the lattice of the epitaxial layer.

In an embodiment of the disclosure, the uniformity of film thickness of the epitaxial layer is less than 3%.

In an embodiment of the disclosure, the crack of the epitaxial layer is less than 3 mm.

In an embodiment of the disclosure, the uniformity of film thickness of the epitaxial layer is less than 3%, and the crack of the epitaxial layer is less than 3 mm.

In an embodiment of the disclosure, in the epitaxial wafer structure, the bow of the epitaxy substrate containing the substrate and the aluminum nitride layer and the epitaxial layer is between −30 μm and 30 μm.

Based on the above, the epitaxial layer formed on the epitaxy substrate of the disclosure through epitaxy growth can have improved quality.

### BRIEF DESCRIPTION OF THE DRAWINGS

FIG. 1A is a schematic partial cross-sectional view of an epitaxy substrate according to an embodiment of the disclosure.

FIG. 1B is a schematic bottom view of an epitaxy substrate according to an embodiment of the disclosure.

FIG. 2 is a schematic partial cross-sectional view of an epitaxial wafer structure according to an embodiment of the disclosure.

### DESCRIPTION OF THE EMBODIMENTS

In the following detailed description, for the purpose of explanation and not limitation, exemplary embodiments revealing specific details are set forth to provide a thorough understanding of various principles of the disclosure. However, it will be clear to those skilled in the art that, thanks to the disclosure, the disclosure can be implemented in other embodiments that depart from the specific details disclosed herein. In addition, descriptions of commonly known devices, methods, and materials may be omitted so as to clearly describe the various principles of the disclosure. Finally, where applicable, the same reference symbols indicate the same components.

The terms “substantially”, “approximately”, “about” and so on used in the text may involve an acceptable tolerance range.

The directional terms used in the text (for example: up and down) are only used with reference to the drawing and are not intended to imply specific orientation. In addition, in order to clearly show the directional relationship between the different drawings, the Cartesian coordinate system (i.e., XYZ rectangular coordinate system) is used to indicate the corresponding direction in some of the drawings.

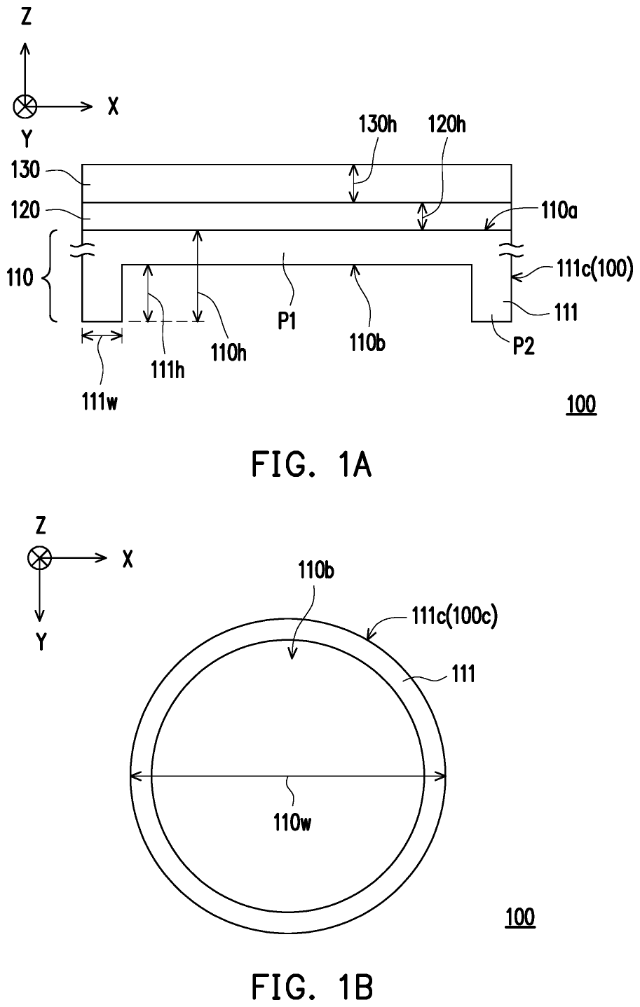

FIG. 1A is a schematic partial cross-sectional view of an epitaxy substrate according to an embodiment of the disclosure. FIG. 1B is a schematic bottom view of an epitaxy substrate according to an embodiment of the disclosure.

Referring to FIG. 1A and FIG. 1B, the epitaxy substrate 100 includes a substrate 110 and an aluminum nitride (AlN) layer 120. The substrate 110 has a first surface 110a and a second surface 110b. The second surface 110b is opposite to the first surface 110a. The aluminum nitride layer 120 is located on the first surface 110a of the substrate 110. The substrate 110 has a ring-shaped protrusion 111 on the edge of the second surface 110b.

In other words, the outer edge 111c of the ring-shaped protrusion 111 is substantially a part of the outer edge 100c of the epitaxy substrate 100.

In other words, considering the overall structure of the substrate 110, the substrate 110 may be composed of a first portion P1 and a second portion P2. That is, the structure of the substrate 110 consists of a first portion P1 and a second portion P2. The second portion P2 surrounds the first portion P1. The second portion P2 corresponds to the ring-shaped protrusion 111. As such, the thickness 110h of the second portion P2 is greater than the thickness of the first portion P1.

In an embodiment, the thickness of the first part P1 is substantially the same everywhere. In an embodiment, the thickness 110h of the second part P2 is substantially the same everywhere.

In this embodiment, the substrate 110 includes a silicon material. In an embodiment, the substrate 110 may be a homogeneous material, and the homogeneous material can no longer allow the component to be separated into different single materials through mechanical methods (such as: crushing, shearing, cutting, sawing, grinding, etc.). In other words, the substrate 110 may not have an interface formed by different materials or different manufacturing processes (such as adhesion).

In an embodiment, the substrate 110 may be a silicon substrate, but the disclosure is not limited thereto. In an embodiment, the substrate 110 may be a silicon carbide (SiC) substrate.

In this embodiment, the thickness 110h of the substrate 110 is approximately between 625 μm (micrometer; μm) and 1000 μm.

In an embodiment, the substrate 110 having the above-mentioned thickness (for example, the thickness of 110h is about 625 μm to 1000 μm) may have improved stress tolerance (for example, the corresponding thermal stress caused by heating or cooling, but the disclosure is not limited thereto). In this way, when the substrate 110 is used for the epitaxial process, the possibility of substrate cracking can be reduced.

In an embodiment, the substrate 110 may have a corresponding thickness 110h by etching, grinding or other suitable methods.

In this embodiment, the height 111h of the ring-shaped protrusion 111 is approximately 10 μm to 200 μm. In other words, the height difference of the substrate 110 on the second surface 110b may be about 10 μm to 200 μm.

In an embodiment, the height 111h of the ring-shaped protrusion 111 may be approximately between 20 μm and 160 μm. In other words, the height difference of the substrate 110 on the second surface 110b may be approximately 20 μm to 160 μm.

In an embodiment, the height 111h of the ring-shaped protrusion 111 may be about 130 μm to 150 μm. In other words, the height difference of the substrate 110 on the second surface 110b may be about 130 μm to 150 μm.

In this embodiment, the width 111w of the ring-shaped protrusion 111 is approximately less than or equal to 5 millimeters (millimeter; mm). In an embodiment, the width 111w of the ring-shaped protrusion 111 is approximately less than or equal to 3 mm. In an embodiment, the width 111w of the ring-shaped protrusion 111 is approximately greater than or equal to 1 mm and less than or equal to 3 mm.

In an embodiment, the thickness of the center of the substrate 110 is relatively thin (compared to the edge with ring-shaped protrusion 111). Therefore, with the ring-shaped protrusion 111 having the above-mentioned width, the supporting force of the substrate 110 can be improved.

In an embodiment, the second surface 110b of the substrate 110 may be provided with corresponding ring-shaped protrusion 111 by etching, grinding or other suitable methods.

In this embodiment, the substrate 110 may be substantially circular, and the ring-shaped protrusion 111 may be a substantially circular ring-shaped protrusion.

In an embodiment, the size 110w of the substrate 110 may be approximately 6 inches to 12 inches. For example, taking the substantially circular substrate 110 as an example, its diameter may be about 6 inches to 12 inches.

In this embodiment, the thickness 120h of the aluminum nitride layer 120 is about 1 nanometer (nm) to 100 nanometers. In an embodiment, the aluminum nitride layer 120 may directly contact the first surface 110a of the substrate 110. In an embodiment, the aluminum nitride layer 120 may completely cover the first surface 110a of the substrate 110.

In an embodiment, the aluminum nitride layer 120 may be formed through epitaxial growth, but the disclosure is not limited thereto.

In an embodiment, since the substrate 110 has the corresponding ring-shaped protrusion 111, and the ring-shaped protrusion 111 has a corresponding height (e.g., between 10 μm to 200 μm) and a width (e.g., less than or equal to 5 mm), after the aluminum nitride layer 120 is formed on the substrate 110, the epitaxy substrate 100 composed of the substrate 110 and the layer (such as the aluminum nitride layer 120) on the substrate 110 can have a corresponding bending or warping (such as: forming a corresponding arch) due to the stress of the aluminum nitride layer 120. In this way, the epitaxy substrate 100 composed of the aforementioned substrate 110 and the layer on the substrate 110 can enhance the quality of the elements or layers (such as: epitaxial layer 240 described later) formed on the substrate when corresponding application (e.g., an epitaxial process) is performed to the epitaxy substrate 100.

In this embodiment, the epitaxy substrate 100 may further include a buffer layer 130. The buffer layer 130 is located on the aluminum nitride layer 120. In an embodiment, the buffer layer 130 may be formed through epitaxial growth, but the disclosure is not limited thereto.

In this embodiment, the lattice of the buffer layer 130 may be between the lattice of the aluminum nitride layer 120 and the lattice of the gallium nitride (GaN) epitaxial layer.

In a possible embodiment, the lattice of the buffer layer 130 may be between the lattice of the aluminum nitride layer 120 and the lattice of the aluminum gallium nitride (AlGaN) epitaxial layer.

In this embodiment, the buffer layer 130 includes a superlattice material. In other words, the structure of the buffer layer 130 may be a stack of multiple materials. For example, the buffer layer 130 may be composed of a stack of aluminum nitride or gallium nitride.

In an embodiment, the buffer layer 130 may directly contact the aluminum nitride layer 120. In an embodiment, the two opposite sides of the aluminum nitride layer 120 may directly contact the first surface 110a of the substrate 110 and the buffer layer 130, respectively.

In an embodiment, the thickness 130h of the buffer layer 130 may be about 1 μm to 6 μm, but the disclosure is not limited thereto.

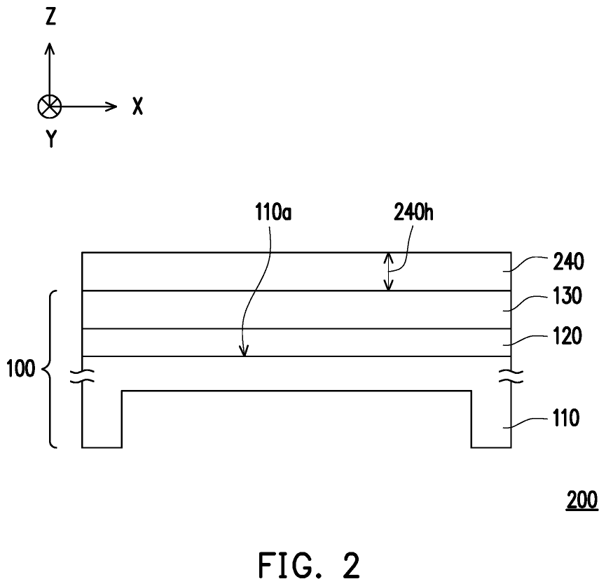

FIG. 2 is a schematic partial cross-sectional view of an epitaxial wafer structure 200 according to an embodiment of the disclosure. It should be noted that, in this embodiment, the epitaxy substrate included in the epitaxial wafer structure 200 is the epitaxy substrate 100 shown in FIG. 1A or FIG. 1B as an example. In other possible embodiments, the epitaxy substrate included in the epitaxial wafer structure 200 may be an epitaxy substrate similar to the epitaxy substrate 100.

Please refer to FIG. 2, the epitaxial wafer structure 200 includes an epitaxy substrate 100 and an epitaxial layer 240. The epitaxial layer 240 is located on the aluminum nitride layer 120. In an embodiment, the layer formed through epitaxial growth may be referred to as epitaxial layer 240.

In an embodiment, if the substrate 110 is a silicon carbide substrate, one surface of the silicon carbide substrate may be a silicon surface or a carbon surface. In the epitaxial growth method described above, if the substrate 110 is a silicon carbide substrate, an epitaxial process may be performed on the silicon surface. That is, in FIG. 2, if the substrate 110 is a silicon carbide substrate, the first surface 110a (marked in FIG. 1A) is a silicon surface.

In this embodiment, the aluminum nitride layer 120 and the epitaxial layer 240 directly contact the two opposite sides of the buffer layer 130, and the lattice of the buffer layer 130 is between the lattice of the aluminum nitride layer 120 and the lattice of the epitaxial layer 240.

In this embodiment, the material of the epitaxial layer 240 is substantially different from the material of the substrate 110.

In an embodiment, the epitaxial layer 240 may include a gallium nitride epitaxial layer 240, but the disclosure is not limited thereto. In an embodiment, the epitaxial layer 240 may be a gallium nitride epitaxial layer 240.

In an embodiment, the epitaxial layer 240 may include a gallium aluminum nitride epitaxial layer 240, but the disclosure is not limited thereto. In an embodiment, the epitaxial layer 240 may be a gallium aluminum nitride epitaxial layer 240.

In an embodiment, the thickness 240h of the epitaxial layer 240 may be approximately 100 nm to 500 nm, but the disclosure is not limited thereto.

In an embodiment, the epitaxial layer 240 formed on an epitaxy substrate that is the same or similar to the epitaxy substrate 100 through epitaxy growth has improved quality.

For example, when using the same or similar epitaxy substrate 100 for epitaxy growth, since the distribution of temperature uniformity is improved, the epitaxial layer 240 can have an improved uniformity. For example, the uniformity (U %) of the thickness 240h of the epitaxial layer 240 (may be simply referred to as: uniformity of film thickness) may be less than 3%. Typically adopted uniformity of film thickness can be: (maximum film thickness-minimum film thickness)/(2×average film thickness); or, film thickness standard deviation (std)/average film thickness value (avg) for estimate.

In an embodiment, before performing epitaxy growth by using the same or similar epitaxy substrate 100, since the substrate 110 and the aluminum nitride layer 120 located thereon may have a large radius of curvature (e.g., approximately greater than −50 km⁻¹) and/or large bow (for example, approximately greater than −140 μm), in this way, the epitaxial layer 240 can have reduced or fewer defects (for example, cracks are approximately smaller than 3 mm). The definition of the radius of curvature or bow can be the same or similar to the definition in the typical wafer quality control, verification or manufacturing fields, so no more details are incorporated herein.

In an embodiment, the thickness of the substrate 110 may be much greater than the thickness of the aluminum nitride layer 120 (e.g., the thickness ratio is 100 times or more; or, the thickness ratio is 1000 times or more). Therefore, the radius of curvature and/or the bow of the substrate 110 and the aluminum nitride layer 120 located thereon can be calculated or estimated through the substrate 110.

In an embodiment, after the epitaxial layer 240 is formed, the bow of the epitaxy substrate 100 containing the substrate 110 and the aluminum nitride layer 120 formed thereon and the epitaxial layer 240 may be between −30 μm and 30 μm. That is to say, before epitaxial growth is performed on the epitaxy substrate 100, the epitaxy substrate 100 may be relatively bent or warped; and after the epitaxial layer 240 is formed through the epitaxy substrate 100, the epitaxy substrate 100 and the epitaxial layer 240 formed thereon may be relatively flat.

In an embodiment, the epitaxy substrate 100 formed by the aforementioned substrate 110 and the layer located thereon has corresponding bending or warping. Therefore, when the epitaxial layer 240 is formed, the stress received by the epitaxial layer 240 can be adjusted by the deformation of the epitaxy substrate 100. In this way, the epitaxial layer 240 formed on the epitaxy substrate 100 can have improved quality (for example, the epitaxial layer 240 can have an improved uniformity of film thickness, and/or have less, minor, or almost no cracks).

In summary, the epitaxial layer formed on the epitaxy substrate of the disclosure through epitaxy growth can have improved quality.

What is claimed is:

1. An epitaxy substrate, comprising:
a substrate having a first surface and a second surface opposite to each other, wherein the substrate has a ring-shaped protrusion on an edge of the second surface; and
an aluminum nitride layer located on the first surface of the substrate.

2. The epitaxy substrate according to claim 1, wherein a height of the ring-shaped protrusion is between 10 μm and 200 μm.

3. The epitaxy substrate according to claim 1, wherein a width of the ring-shaped protrusion is less than or equal to 5 mm.

4. The epitaxy substrate according to claim 1, wherein a thickness of the aluminum nitride layer is between 1 nm and 100 nm.

5. The epitaxy substrate according to claim 1, wherein a thickness of the substrate is between 625 μm and 1000 μm.

6. The epitaxy substrate according to claim 1, wherein the substrate comprises a silicon material.

7. The epitaxy substrate according to claim 1, further comprising:
a buffer layer located on the aluminum nitride layer, wherein a lattice of the buffer layer is between a lattice of the aluminum nitride layer and a lattice of a gallium nitride epitaxial layer.

8. The epitaxy substrate according to claim 7, wherein the buffer layer comprises a superlattice material.

9. The epitaxy substrate according to claim 1, wherein a bow of the epitaxy substrate is greater than −140 μm.

10. The epitaxy substrate according to claim 1, wherein the structure of the substrate consists of a first portion and a second portion, the second portion surrounds the first portion and corresponds to the ring-shaped protrusion, and the thickness of the second portion is greater than the thickness of the first portion.

11. An epitaxial wafer structure, comprising:
an epitaxy substrate, comprising:
a substrate having a first surface and a second surface opposite to each other, wherein the substrate has a ring-shaped protrusion on an edge of the second surface; and
an aluminum nitride layer located on the first surface of the substrate; and
an epitaxial layer located on the aluminum nitride layer.

12. The epitaxial wafer structure according to claim 11, wherein:
a height of the ring-shaped protrusion is between 10 μm and 200 μm;
a width of the ring-shaped protrusion is less than or equal to 5 mm;
a thickness of the aluminum nitride layer is between 1 nm and 100 nm; or
a thickness of the substrate is between 625 μm and 1000 μm.

13. The epitaxial wafer structure according to claim 11, wherein the substrate comprises a silicon material.

14. The epitaxial wafer structure according to claim 11, further comprising:
a buffer layer, wherein the aluminum nitride layer and the epitaxial layer directly contact two opposite sides of the buffer layer, and a lattice of the buffer layer is between a lattice of the aluminum nitride layer and a lattice of the epitaxial layer, and wherein the epitaxial layer is a gallium nitride epitaxial layer.

15. The epitaxial wafer structure according to claim 14, wherein the buffer layer comprises a superlattice material.

16. The epitaxial wafer structure according to claim 11, wherein:
a uniformity of film thickness of the epitaxial layer is less than 3%; or
a crack of the epitaxial layer is less than 3 mm.

17. The epitaxial wafer structure according to claim 11, wherein a bow of the epitaxy substrate containing the substrate and the aluminum nitride layer and the epitaxial layer is between −30 μm and 30 μm.

18. The epitaxial wafer structure according to claim 11, wherein the structure of the substrate consists of a first portion and a second portion, the second portion surrounds the first portion and corresponds to the ring-shaped protrusion, and the thickness of the second portion is greater than the thickness of the first portion.
